(19) United States
(12) Patent Application Publication
(10) Pub. No.: US 2011/0250528 A1
(43) Pub. Date: Oct. 13, 2011

(54) METHOD FOR CORRECTING IMAGE PLACEMENT ERROR IN PHOTOMASK

(75) Inventor: Sung Hyun OH, Cheongju-si (KR)

(73) Assignee: HYNIX SEMICONDUCTOR INC., Icheon-si (KR)

(21) Appl. No.: 13/083,729

(22) Filed: Apr. 11, 2011

(30) Foreign Application Priority Data
Apr. 13, 2010 (KR) 10-2010-0033867

(51) Int. Cl. G03F 1/00

(52) U.S. Cl. 430/5

(57) ABSTRACT

A method for correcting an image placement error in a photomask includes, forming a photomask including a light absorbing layer formed on a frame region of a substrate and a mask pattern formed on a field region inside the frame region, measuring a first registration error of the photomask, and etching a portion of the light absorbing layer on the frame region to induce a second registration error for compensating the first registration error.

### CROSS-REFERENCES TO RELATED APPLICATIONS

The present application claims priority under 35 U.S.C. 119(a) to Korean Application No. 10-2010-0033867, filed on Apr. 13, 2010, in the Korean intellectual property Office, which is incorporated herein by reference in its entirety set forth in full.

### BACKGROUND

Exemplary embodiments of the present invention relate to semiconductor technology, and more particularly, to a method for correcting an image placement error in a photomask.

As a feature size and pitch of a semiconductor device decrease, it becomes more important to reduce an image placement error in a photomask. As semiconductor devices are scaled down to less than 45 nm nodes, fine pattern forming techniques such as a double exposure technique (DET) and a double patterning technique (DPT) are being used for pattern forming. In order to realize such techniques, efforts are being made to suppress an image placement error very strictly. According to the ITRS road map, a DET or DPT technique for less than 45 nm nodes requires an image placement error (i.e., a registration error) of less than 4 nm. However, it is now difficult to suppress a registration error to such a level.

### SUMMARY

An embodiment of the present invention relates to a method for correcting an image placement error in a photomask.

In an exemplary embodiment of the present invention, a method for correcting an image placement error in a photomask includes forming a photomask including a light absorbing layer formed on a frame region of a substrate and a mask pattern formed on a field region inside the frame region, measuring a first registration error of the photomask, and inducing a second registration error for compensating the first registration error, by etching a portion of the light absorbing layer on the frame region.

In another exemplary embodiment of the present invention, a method for correcting an image placement error in a photomask includes forming a photomask, measuring a first registration error of the photomask, and attaching a pellicle on the photomask while applying an attaching pressure, wherein a local attaching pressure, different from the attaching pressure, is applied to a portion of the attaching surface between the photomask and the pellicle to induce a local change in the flatness of the pellicle to cause a second registration error for compensating the first registration error.

### BRIEF DESCRIPTION OF THE DRAWINGS

The above and other aspects, features and other advantages will be more clearly understood from the following detailed description taken in conjunction with the accompanying drawings, in which:

FIGS. 1 to 4 are diagrams illustrating a method for correcting an image placement error in a photomask according to an exemplary embodiment of the present invention; and

FIGS. 5 to 9 are diagrams illustrating a method for correcting an image placement error in a photomask according to another exemplary embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

The embodiments of the present invention relate to a method for correcting an image placement error (e.g., a pattern registration error) in a photomask by etching a light absorbing layer such that a stress is induced, in order to compensate a generated image placement error. Here, this method relates to a phenomenon where a registration change of a photomask is induced by a stress induced when etching a light absorbing layer (or a light absorber) or a light blocking layer. The embodiments of the present invention also relate to a method for correcting an image placement error in a photomask by locally changing a pellicle flatness in order to compensate a generated image placement error. Here, this method relates to a phenomenon where a registration change is induced by a pellicle flatness change induced when attaching a pellicle on a photomask (or a reticle).

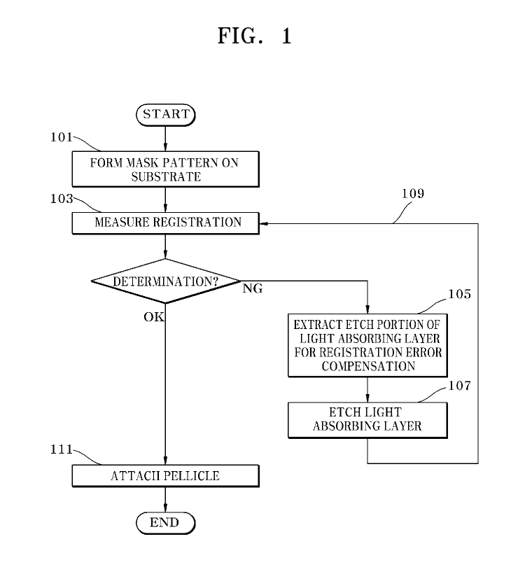

FIGS. 1 to 4 are diagrams illustrating a method for correcting an image placement error in a photomask according to an exemplary embodiment of the present invention.

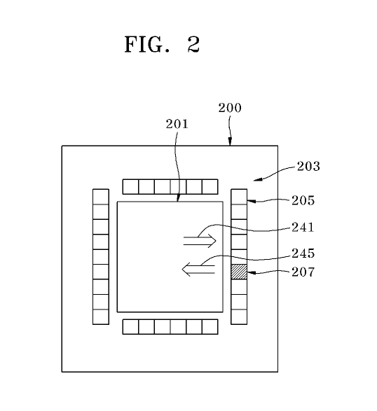

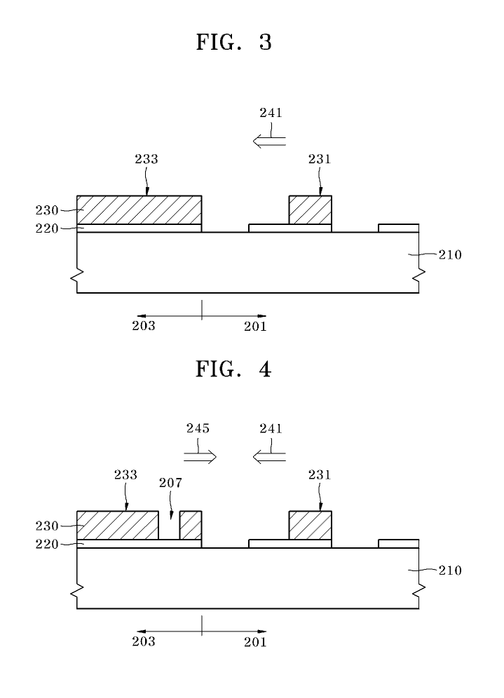

Referring to FIG. 1, a method for correcting an image placement error in a photomask according to an exemplary embodiment of the present invention includes steps which will be described below in more detail. First, a mask pattern is formed on a transparent substrate (101). As illustrated in FIGS. 2 and 3, a photomask 200 may include a mask pattern 231 formed on a transparent quartz substrate 210. Here, the mask pattern 231 to be transferred onto a wafer is formed in a field region 201 of the photomask 200. In the case of an attenuated phase shift mask (PSM), a phase shift layer 220 including a molybdenum silicon (MoSi) layer is formed on the substrate 210, a light absorbing layer (or a light absorber) 230 or a light blocking layer of a chrome (Cr) layer is formed on the phase shift layer 220. The light absorbing layer 230 of a frame pattern 233 covers a frame region 203 outside the field region 201 where the mask patterns 231 are formed, which is a region light-blocked by a blade in an exposure process and is a region to which a pellicle is attached.

Next, the registration of the mask patterns 231 is measured in a map format (103 of FIG. 1). When the mask patterns 231 are formed, a first registration error 241 may be induced in various vector directions. According to the exemplary embodiment of the present invention, the first registration error 241 may be compensated by inducing a local stress in the photomask 200. In order to compensate the first registration error 241, the light absorbing layer 230 of the frame pattern 233 on the frame region 203 is locally etched. Consequently, a second registration error 245 is induced by a local stress induced by the etching of the light absorbing layer 230, and thus the first registration error 241 is compensated by the second registration error 245.

In order to compensate the first registration error 241 by the second registration error 245, a portion to be stressed by etching, that is, a portion (207 of FIG. 2) of the light absorbing layer 230 to be etched (an etch portion) is extracted first (107 of FIG. 1). The etch portion 207 is set by beforehand measuring the second registration errors induced by the local etching at various portions and extracting the point to induce the second registration error 245 for compensating the first registration error 241 from the measured data. Here, a virtual scale 205 is introduced on the frame region 203, the etch portions are subdivided into unit portions, and one of the unit portions is selected as the etch portion 207.

After extraction of the etch portion 207, the portion of the light absorbing layer 230 on the frame region 203 corresponding to the etch portion 207 is selectively etched. Accordingly, a hole is formed in the selected etch portion 207. The etching of the light absorbing layer 230 induces a local stress, and the local stress changes the stress distribution of the photomask 200. The stress distribution change induces a second registration error 245 in the photomask 200. The second registration error 245 compensates for the first registration error 241, thereby effectively correcting the registration error. Accordingly, the image placement error may be corrected. After the performing of the etching process for registration error correction, the registration on the photomask 200 is re-measured (109). If it is determined to be normal, a pellicle is attached on the photomask 200 (111).

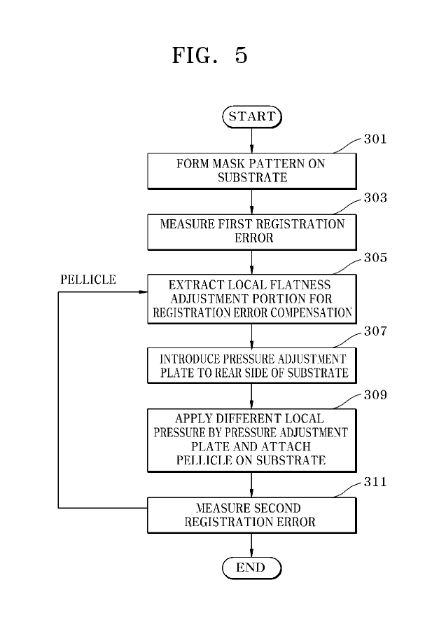

FIGS. 5 to 9 are diagrams illustrating a method for correcting an image placement error in a photomask according to another exemplary embodiment of the present invention. According to the another exemplary embodiment of the present invention, a registration error induced in a photomask is compensated by using the fact that a registration error is induced depending on the flatness of a pellicle.

Referring to FIG. 5, a method for correcting an image placement error in a photomask according to another exemplary embodiment of the present invention includes steps which will be described below in more detail. First, a mask pattern is formed on a transparent substrate (301), and the registration of mask patterns is measured in a map format (303).

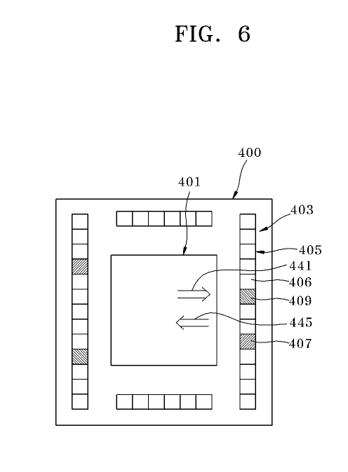

As illustrated in FIG. 6, a first registration error 441 may be induced in various vector directions in the mask patterns formed on a field region 401 of a photomask 400. According to the another exemplary embodiment of the present invention, the first registration error 441 may be compensated by a second registration error 445 that is caused by a local change in the flatness of a pellicle. For a local change in the flatness of a pellicle, an attaching surface portion 405 on a frame region 403, to which a pellicle is attached, is subdivided into unit regions 406, 407 and 409.

In order to compensate the first registration error 441, the portions 407 and 409 to adjust the local flatness of a pellicle are extracted (305 of FIG. 5). As illustrated in FIG. 9, when a pellicle 600 is attached on the photomask 400, a frame 601 with the pellicle 600 attached thereto is used. Adhesive layers 602 and 605 are formed between the frame 601 and the photomask 400. If the local thicknesses of the adhesive layers 602 and 605 are different from each other, a height of the attached pellicle 600 at a position of the adhesive layer 602 is different from the height of the attached pellicle 600 at the position of the other adhesive layer 605. Here, the local height difference means that the flatness of the pellicle 600 changes locally. If the flatness of the pellicle 600 changes locally, a second registration error 445 depending on the flatness change is induced. Therefore, the second registration error 445 compensates for the first registration error 441 generated on the photomask 200.

In order to compensate the first registration error 441 by the second registration error (445 of FIGS. 6 and 9), portions (407 and 409 of FIG. 6) to adjust the flatness of a pellicle are extracted (305 of FIG. 5). The local flatness adjustment may be implemented by applying different pressures to the unit regions 406, 407 and 409 when applying a pressure to the attaching surface (405 of FIG. 6) for attachment of the pellicle (600 of FIG. 9). For example, a normal attaching pressure is applied to the first unit regions 406, a relatively high attaching pressure is applied to the second unit regions 407, and a relatively low attaching pressure is applied to the third unit regions 409. Then, when attaching the pellicle 600, the thickness of the first adhesive layer portion (602 of FIG. 9) and the thickness of the second adhesive layer portion (605 of FIG. 9) differ substantially from each other, thus inducing the difference of heights (604 of FIG. 9) causing a local bending of the pellicle 600. If the flatness of the pellicle 600 is locally changed, a second registration error 445 is induced by the flatness change. Therefore, the second registration error 445 compensates for the first registration error 441.

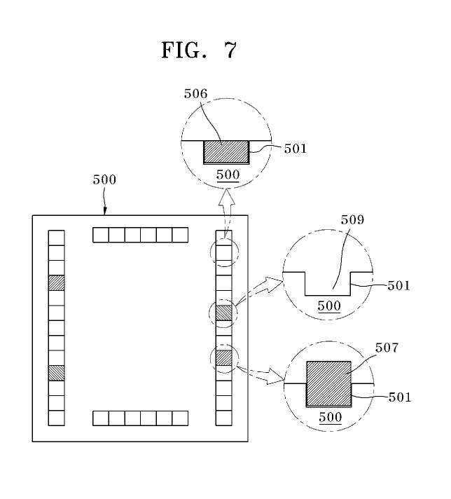

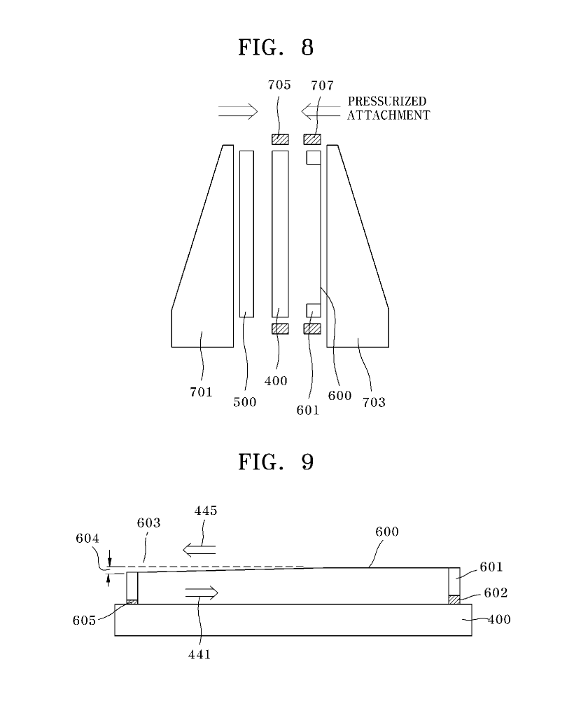

A process for adjusting the attaching pressure locally will be described below in detail. The flatness adjustment portions 407 and 409 are extracted in consideration of the vector direction of the second registration error 445 to be induced. At this point, the first adjustment portion 407 requiring a relatively high attaching pressure and the second adjustment portion 409 requiring a relatively low attaching pressure are extracted in a divided manner, and pressure-adjusting blocks 507 and 506 are placed at the corresponding positions of a pressure-adjusting plate (500 of FIG. 7) (307 of FIG. 5). As illustrated in FIG. 8, when the pellicle 600 is attached to the photomask 400 in a pellicle attaching equipment, the pressure-adjusting plate 500 is placed at the rear side of the photomask 400 to locally change the uniform attaching pressure applied from a lower pressurizing plate 710 and an upper pressurizing plate 703 that face each other (309 of FIG. 5).

The pressure-adjusting plate 500 has pressure-adjusting grooves 501 formed at the positions corresponding to the unit regions of the attaching surface (405 of FIG. 6), and pressure-adjusting blocks 507 and 506 to be inserted in the pressure-adjusting grooves 501. The pressure-adjusting block 507 is inserted in the first pressure-adjusting groove (501 of FIG. 7) corresponding to the first adjustment portion (407 of FIG. 6) requiring a relatively high attaching pressure. The pressure-adjusting block 507 has a height to protrude from the pressure-adjusting plate 500. Therefore, the protruding portion induces a concentration of pressure at the contact portion of the rear side of the photomask (400 of FIG. 8). The pressure-adjusting block is not inserted in the second pressure-adjusting groove 501 corresponding to the second adjustment portion (409 of FIG. 6) requiring a relatively low attaching pressure, which has an empty shape 509, thus transmitting a relative low attaching pressure. The normal pressure-adjusting block 506 is inserted in the other pressure-adjusting groove 501, and the normal pressure-adjusting block 506 forms a flat surface with the surface of the pressure-adjusting plate 500, thus transmitting a normal attaching pressure.

By using the pressure-adjusting plate 500, the pellicle 600 mounted on a pellicle holder 707 is attached on the photomask 400 mounted on a mask holder 705, thereby intentionally inducing a local flatness change in the pellicle 600. The second registration error 445 induced by the flatness change compensates for the first registration error 441 induced in the photomask 400, thereby correcting the registration error. After the attachment of the pellicle 600, a secondary registration measurement is performed (311 of FIG. 5). If it is abnormal, the attachment of the pellicle 600 is again performed.

The embodiments of the present invention locally adjust the pressure when etching the light absorbing layer and attaching the pellicle, thereby compensating a registration error in the photomask. Accordingly, an image placement error can be suppressed within the strict range required for fabrication of a semiconductor device with less than 45 nm nodes.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method for correcting an image placement error in a photomask, comprising:
forming a photomask including a light absorbing layer formed over a frame region of a substrate and a mask pattern formed on a field region inside the frame region;
measuring a first registration error of the photomask; and
inducing a second registration error for compensating the first registration error, by etching a portion of the light absorbing layer over the frame region.

2. The method of claim 1, wherein the measuring of the first registration error of the photomask comprises:
obtaining the first registration errors of the mask patterns in a map format.

3. The method of claim 1, wherein the inducing of the second registration error comprises:
selecting a position of the light absorbing layer to induce a local stress for compensating the first registration error; and
selectively etching the selected position of the light absorbing layer.

4. The method of claim 3, wherein the selecting of the position of the light absorbing layer comprises:
measuring a local etching position of the light absorbing layer and a correlation between the second registration errors induced by the local etching;
calculating the second registration error value for compensating the first registration error; and
extracting the local etching position of the light absorbing layer corresponding to the calculated second registration error value from the measured correlation between the second registration errors.

5. The method of claim 4, wherein the extracting of the local etching position of the light absorbing layer comprises:
introducing a virtual scale on the frame region to subdivide the frame region into unit portions; and
setting each of the unit portions as an independent etch portion.

6. The method of claim 3, wherein the selective etching of the selected portion of the light absorbing layer comprises:
etching the light absorbing layer portion to form a hole on the selected portion of the light absorbing layer.

7. The method of claim 1, further comprising, after the inducing of the second registration error:
re-measuring the registration of the photomask; and
attaching a pellicle on the photomask.

8. The method of claim 1, wherein the inducing of the second registration error comprises:
setting a virtual scale at the light absorbing layer portion to subdivide the etch portion into unit portions;
extracting a target etch portion from the unit portions subdivided by the virtual scale; and
selectively etching the target etch portion to induce a local address by the etching.

9. A method for correcting an image placement error in a photomask, comprising:
forming a photomask;
measuring a first registration error of the photomask; and
attaching a pellicle on the photomask while applying an attaching pressure,
wherein a local attaching pressure, different from the attaching pressure, is applied to a portion of the attaching surface between the photomask and the pellicle to induce a local change in the flatness of the pellicle to cause a second registration error for compensating the first registration error.

10. The method of claim 9, wherein the attaching of the pellicle on the photomask comprises:
setting a virtual scale to subdivide the attaching surface of the photomask into unit regions;
extracting a pressure adjusting region, to which the local attaching pressure is to be applied, from the unit regions subdivided by the virtual scale;
introducing a pressure adjusting plate at the rear side of the photomask to apply the local pressure to the pressure adjusting region by inserting or not inserting a pressure adjusting block in a pressure adjusting groove corresponding to the pressure adjusting portion; and
attaching the pellicle on the photomask by applying the attaching pressure to the pellicle and the pressure adjusting plate.

11. The method of claim 9, wherein the measuring of the first registration error comprises:
obtaining the first registration errors of the mask patterns in a map format.

12. The method of claim 9, wherein the causing of the second registration error comprises:
selecting the pressure adjusting region position on the pellicle to apply a local attaching pressure for compensating the first registration error; and
locally changing the flatness of the pellicle by applying the local attaching pressure to the selected pressure adjusting region position.

13. The method of claim 12, wherein the selecting of the pressure adjusting region position comprises:
measuring a local position on the pellicle and a correlation between the second registration errors caused by the local change of the flatness of the pellicle induced by the application of the local attaching pressure;
calculating the second registration error value for compensating the first registration error; and
extracting a position of the pellicle corresponding to the calculated second registration error value.

14. The method of claim 13, wherein the selecting of the pressure adjusting region position comprises:
introducing a virtual scale on the pellicle to subdivide the attaching surface into unit portions; and
setting each of the unit portions as a portion to which the local pressure is to be applied independently.
